(19) United States
(12) Patent Application Publication
(10) Pub. No.: US 2018/0145497 A1
(43) Pub. Date: May 24, 2018

(54) METHOD TO UTILIZE MULTIPLE CONFIGURATION SOFTWARE FOR DF/CAFI BREAKERS

(71) Applicant: SCHNEIDER ELECTRIC USA, INC., Andover, MA (US)

(72) Inventor: Andi Jakupi, Marion, IA (US)

(73) Assignee: SCHNEIDER ELECTRIC USA, INC., Andover, MA (US)

(21) Appl. No.: 15/360,007

(22) Filed: Nov. 23, 2016

(51) Int. Cl. H02H 1/00; H02H 3/16; H02H 3/05; G01R 31/02

(52) U.S. Cl. CPC H02H 1/0092; H02H 3/16; G01R 31/025; H02H 3/05; H02H 1/0015

(57) ABSTRACT

An dual function/combination arc fault interrupter (DF/CAFI) circuit breaker or other circuit interrupting device is equipped to select from multiple load profiles for use with an on-board arc fault detection algorithm. The DF/CAFI breaker is provided with a selector mechanism to switch between the multiple profiles in the different look up tables preloaded in the breaker firmware. The installer may select a particular look up table with a particular branch load profile for arc events upon installation for an anticipated load profile. After installation, the user or installer may switch to a different Look Up Table with different load profile parameters upon noticing an excess of nuisance tripping.

### FIELD OF THE INVENTION

The invention relates to the field of arc fault detection, and more particularly, to an approach for improving immunity against nuisance tripping in arc fault circuit interruption devices.

### BACKGROUND

An arc fault circuit interrupter has an arc detection device used to detect hazardous arcing events on a circuit, and in response, to trip a circuit interrupter and remove power to the circuit. These arc fault devices may include circuit breakers such as Combination Arc Fault Circuit Interrupters (for parallel and series arcs) and include Dual Function (Arc Fault (AF) and Ground Fault (GF)) circuit interrupters of the Combination type. Other arc fault circuit interrupter devices other than circuit breakers might be placed at outlet receptacles or the like.

Arc fault detection is a probability determination. Sometimes the arc detection algorithm implementation may have a hard time providing a clean distinction between the current “signature” of some loads and a real arc fault event and thus the detection algorithm errors on the arc fault side and causes nuisance trips. Thus, an arc fault detection device may be subject to unwanted tripping, such as nuisance tripping or false positive tripping, which is an inconvenience to the user, or worse. Over the past decade, improvements have been made to detection algorithms used in arc fault detection devices in order to increase immunity against unwanted tripping. The detection algorithm for a known breaker is paired in a single program with the multiple parameters stored as pre-computed look-up-table (LUT) values, necessary for determining the “signature” of an arc event. A complex arc event signature is defined by more parameters, which makes it easier to distinguish between different types of tripping events. Thus, more signatures will yield more and better discrimination of nuisance trip signatures versus real arcing event tripping. However, there are practical limits on the speed and expense of computing power for the detection algorithm, and the space available for same, for determining a broad range of arcing event signatures, especially within a miniature circuit breaker (MCB).

Known arc fault breakers are generally supplied with a “one size fits all” combination algorithm/LUT. This default algorithm and LUT may cover most of the load combinations in a house, and e.g. work well in the kitchen with various kitchen specific loads and/or bedroom loads, but it might not be as robust with bathroom loads or living room loads. Meanwhile another algorithm/LUT might have a better set of detection parameters that perform extremely well with bathroom and living room loads but not be loaded in the arc fault breaker.

Given that an arc fault detection device is expected to perform for a wide range of branch circuit loads not all of which can be accommodated by a single algorithm/LUT, and the arc fault breaker may have an installed lifetime of decades, thus encountering unforeseeable loads and load combinations over its life span, nuisance tripping may occur with unwanted frequency.

Further, it will be apparent from this discussion that due to the nature of arc fault expression and the complexity and variety of the loads which may be installed in e.g. a home, it is difficult to prevent nuisance tripping completely. At the same time it is very difficult to implement a nuisance prevention scheme covering all the possible combination loads a home might have.

### SUMMARY

Aspects of the present invention can improve arc fault circuit breaker capability in a miniature circuit breaker (MCB) or other arc fault protection device and reduce nuisance tripping in an arc fault breaker, by separating the detection algorithm from the values in the pre-computed look-up-table (LUT) used with the algorithm. The precomputed LUT values are arranged in different LUTs to specifically address more particular groups of loads. Then, multiple LUT tables can be stored within the breaker and utilized with their characteristic load profiles and the detection algorithm to increase the scope of arc fault detection and be selected to decrease the amount of nuisance tripping. In one aspect of the invention, the user of the arc fault breaker can perform an LUT change for the arc fault breaker manually if the user notices the present configuration of arc detection is causing excessive nuisance tripping.

The present disclosure provides an arc fault detection device and method, which utilizes multiple LUTs which are switchable for use within the arc fault breaker. It will be noted that, due to cost prohibitions on available memory and processing power, the breaker can typically only run the algorithm with one set of parameters (LUT) at a time. If excess nuisance tripping is determined, a notice can be given to the operator and a change of LUTs can be initiated. For example, an adaptive arc fault detection device and method, such as described in Assignee's co-owned US patent application publication no. 2016/0149389, (also WO 2014/209311) entitled Adaptive Arc Fault Detection Trip Decision Buffer, to Jeremy D. Schroeder, may determine whether a detected arc fault tripping event is an unwanted tripping event and may be used to indicate it is time to initiate the change of LUTs within the arc fault breaker in accordance with the present invention. The user of the breaker may then choose a more selective LUT carried within the breaker to work with the detection algorithm and reduce the frequency of nuisance tripping.

### BRIEF DESCRIPTION OF THE DRAWINGS

The description of the various exemplary embodiments is explained in conjunction with the appended drawings, in which:

FIG. 1 illustrates a block diagram of some exemplary components of a circuit protective device, and especially a miniature circuit breaker, suitable for use with aspects of the present invention;

FIG. 2 illustrates a block diagram of an exemplary memory architecture in accordance with aspects of the present invention;

FIG. 3 illustrates a flow chart for firmware operation in accordance with aspects of the present invention;

FIG. 4 is a flow chart for LUT selection in accordance with aspects of the present invention.

### DETAILED DESCRIPTION

As an initial matter, it will be appreciated that the development of an actual commercial application incorporating aspects of the disclosed embodiments will require many implementation specific decisions to achieve the developer's ultimate goal for the commercial embodiment. Such implementation specific decisions may include, and likely are not limited to, compliance with system related, business related, government related and other constraints, which may vary by specific implementation, location and from time to time. While a developer's efforts might be complex and time consuming in an absolute sense, such efforts would nevertheless be a routine undertaking for those of skill in this art having the benefit of this disclosure.

It should also be understood that the embodiments disclosed and taught herein are susceptible to numerous and various modifications and alternative forms. Thus, the use of a singular term, such as, but not limited to, “a” and the like, is not intended as limiting of the number of items. Similarly, any relational terms, such as, but not limited to, “top,” “bottom,” “left,” “right,” “upper,” “lower,” “down,” “up,” “side,” and the like, used in the written description are for clarity in specific reference to the drawings and are not intended to limit the scope of the invention.

Further, words of degree, such as “about,” “substantially,” and the like may be used herein in the sense of “at, or nearly at, when given the manufacturing, design, and material tolerances inherent in the stated circumstances” and are used to prevent the unscrupulous infringer from unfairly taking advantage of the invention disclosure where exact or absolute figures and operational or structural relationships are stated as an aid to understanding the invention.

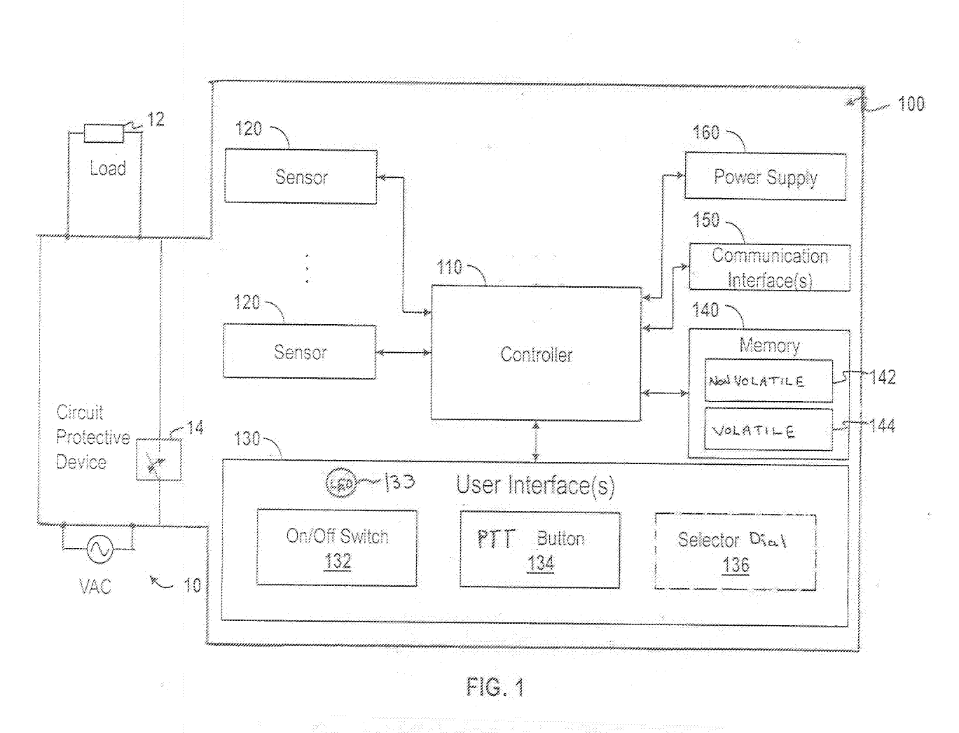

FIG. 1 illustrates a block diagram of some exemplary components of a circuit protective device, exemplified herein as a Dual Function/Combined Arc Fault Interrupter (DF/CAFI) arc fault Circuit Breaker device 100, as an aid to understanding aspects of the invention. As shown in FIG. 1, the breaker 100 may include a controller 110, sensors 120, user interfaces 130, a memory 140, a communication interface 150, a power supply 160, along with the separable contacts 114 for opening the circuit.

The sensors 120 may monitor or sense activities of the circuit breaker 100 such as when it is placed in an ON position and in a TRIPPED position. Sensors 120 can further include a voltage sensor or a current sensor, which can be used to sense electrical characteristics, such as a voltage or current, through the circuit 10 or a load 12 connected to the circuit 10. It will be understood that the sensors 120 may also include, or be connected to, signal conditioning circuits, threshold detectors, filters and analog-to digital converters for processing the sensed data prior to output to the controller 110.

The user interface(s) 130 may include a plurality of user input devices through which a user can input information or commands to the circuit breaker 100. The user interfaces 130 can include the already present On/Off switch 132 and Push To Test (PTT) button 134 as known in the art; and if desired, a Selector dial or switch 136 may be added for directly selecting the desired LUT. The user interface(s) 130 can include one or more light emitting diodes (LEDs) 133 as well. The communication interface(s) 150 can include communication circuitry for conducting line-based communications with an external device such as a UART, SPI, I2C, CAN, USB or Ethernet cable interface, or for conducting wireless communications with an external device through a wireless personal area network, a wireless local area network, a cellular network or wireless wide area network. The communication interface(s) 150 can be used to receive updates to the LUT database, which is made simpler through the separation of the detection algorithm from the LUTs, thus allowing specific memory address blocks to each LUT.

The memory 140 includes nonvolatile memory 142 and volatile memory 144 and can store a variety of computer executable code or programs, including the algorithm and the LUT selections, which when executed by the controller 110, controls the operations of the circuit breaker 100 as further explained below.

The controller 110 is in communication with the memory 140. The controller 110 is a processing system, such as a microcontroller or microprocessor or a state machine, which controls the operations of the circuit breaker 100, including the circuit breaker operation as described herein in the present disclosure. For example, the controller 110 can be configured to monitor through one or more of the sensors 120 a trip sequence implemented by the circuit breaker 100 as a function of time during a read out operation to indicate the selection of a particular LUT, as well as identifying a type of diagnostic condition as described in Assignee's co-owned U.S. Pat. No. 8,243,411 to Brett Larson, entitled Electronic Miniature Circuit Breaker With Trip Indication Using The Breaker Tripping Function As The Feedback Mechanism, such as a type of fault condition from a prior occurrence of a trip event, or other diagnostic information through one or more of the user interfaces 130.

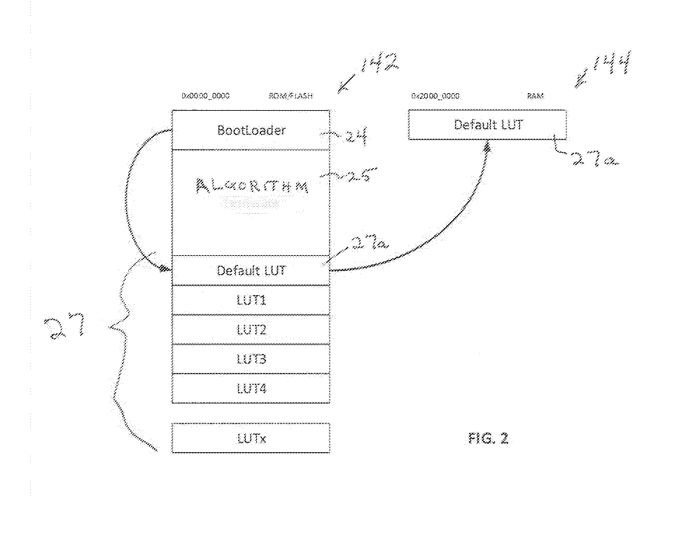

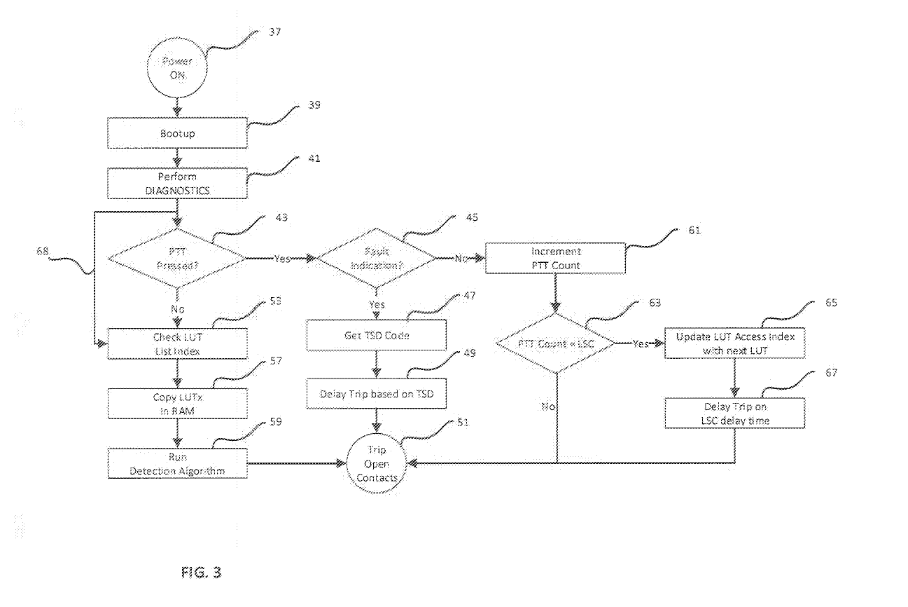

FIG. 2 diagrams the arc fault breaker volatile memory 144 and nonvolatile memory 142 contents including a bootloader 24, an arc detection algorithm 25, and a plurality of LUTs, collectively 27, which includes the default LUT 27a used for arc detection operations. It will be appreciated here that the nonvolatile, e.g. flash/ROM, memory 142 has separated the detection algorithm from the parameters/values it will use which are contained in the list of customized-load LUT tables; and that the LUTs 27 are stored in known memory locations for the detection algorithm 25 to utilize. Referring also to FIG. 3, upon power up, the bootloader 24 runs a routine to load the default LUT 27a into the volatile memory 21, e.g. RAM, for speed of processing, and continues normal protection operations running the detection algorithm 25 utilizing this LUT. Any of the various LUTs 27 can be selected as the initial/default LUT by operation of selectors at the breaker.

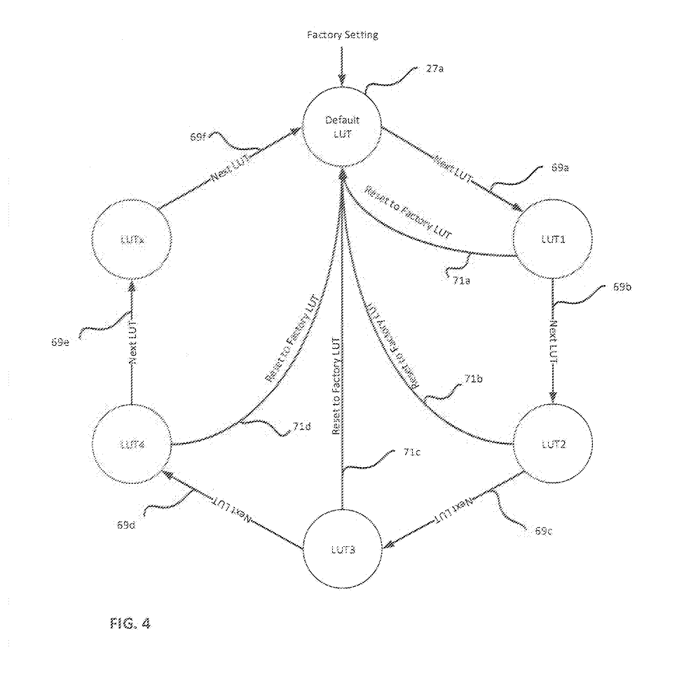

Referring also to FIGS. 3 and 4, the default LUT selection 27a is set at manufacturing, but it can be switched to one of the other LUTs 27 via operation of the Push-To-Test (PTT) switch 31 and On/Off switch 33 combination, which are typically already in place on an arc fault MCB 100. Alternatively, if space is available, a dedicated push button (not shown) or a mechanical dial switch, or both, might be added to facilitate LUT selection. To indicate which LUT is selected, a Trip Indication with a delay as discussed in the aforementioned U.S. Pat. No. 8,243,411, or the LED indicator 133 blinking a certain pattern, could offer this information to the user.

A suggested firmware operation for managing operation of the detection algorithm 25 to trip the breaker 100 and selection of the default LUT 27a is described in the flow chart of FIG. 3. While described in the context of firmware components, it will be realized that other forms of software can be utilized within the scope of the invention. At step 37 the circuit breaker 100 is switched on. The bootloader routine 24 is activated at step 39. Necessary diagnostics are then run at step 41. During diagnostics the PTT button status is checked at step 43 to see if it is pressed. If “Yes” a fault indication status is checked for at step 45. If a fault indication is present, the routine fetches the “time saver diagnostic” (TSD) code, which is a timed trip delay according to aforementioned U.S. Pat. No. 8,243,411, at step 47, and a trip command is issued and held at step 49 until tripping (i.e. opening of the contacts) is accomplished to indicate the time delay at step 51. If the check at step 43 indicates the PTT button has not been pressed (i.e. a “NO”), the controller 110 will continue to check the LUT list index at step 53 to determine the identity of the default LUT 27a and copy it into RAM at step 57 for use in running the detection algorithm at step 59 for operation of the circuit interrupter, i.e. opening the contacts, at step 51.

If there is no fault indication at step 45 the PTT count is incremented at step 61. The PTT count is checked at step 63, and if PTT count equals the appropriate level (e.g. above a certain number of PTT button presses) it is recognized as an LUT Switch Count (LSC) and activates the LUT access index at step 65 and selects a new default LUT corresponding to the LSC. A time delay identifying the new LUT is entered at step 67 for tripping the contacts at a predetermined time delay to identify the selected LUT. The identification of the selected LUT can also be done with an indication from the LED 133 as explained above. It needs to be noted that while the breaker is checking the PTT state (pressed or not pressed) at step 43, it continues its protective function with the detection algorithm using the current LUT at step 53 as indicated by line 68. This state will continue unless and until a update/reset is issued at step 65 with the new LUT being selected.

Referencing FIG. 4, a basic outline of LUT selection is set forth. Other methods and means of switching between LUTs can be achieved, e.g. using a dial switch. From the user's point of view, each LUT can be dedicated to a particular load configuration/room, for example kitchen, bedroom, bathroom, garage, living room, etc. Thus the selectable LUTs might be designated by common household room locations and identified as one of “Kitchen Configuration,” “Living Room Configuration,” etc. to make selection intuitive for the user/installer. Each LUT can, for example, be UL Certified in the lab and verified under the standard testing procedures. As seen in FIG. 4, the user can switch, at steps 69a, 69b, 69c, 69d, 69e, 69f, between LUTs in a sequence order and if the entire limit/list of LUTs is consumed it will arrive back to the default LUT 27a. Alternatively, with a certain number and/or combination of PTT/On-Off switch presses/selections, the controller 110 can jump directly to the default LUT 27a at steps 71a, 71b, 71c, 71d, as shown in the diagram.

The suggested firmware design separating the detection algorithm from the targeted parameters of multiple LUTs thus enables the load-specific configurations of LUTs to be selectable by the user/installer. This can reduce nuisance tripping, increase robustness on arc fault detection and reduce product returns of arc fault breakers from customers. Allowing the firmware to load an LUT in memory based on the user selection/configuration during power up and then use this LUT for protection makes the firmware very flexible for updates in the future as new loads become prevalent in the residential or commercial marketplaces. Since LUTs are pre-allocated in fixed memory regions, it is feasible to update/replace/add or remove them, either remotely or on-site, to increase the flexibility of the arc fault breaker in the future.

While particular embodiments and applications of the present disclosure have been illustrated and described, it is to be understood that the present disclosure is not limited to the precise construction and compositions disclosed herein and that various modifications, changes, and variations can be apparent from the foregoing descriptions without departing from the scope of the invention as defined in the appended claims.

1. An arc fault circuit interrupter device having:
a controller;
volatile and nonvolatile memories;
an arc detection algorithm and a plurality of Look Up Tables including a default Look Up Table and a second Look Up Table, each Look Up Table storing separate detection parameters for different load profiles, all stored in the nonvolatile memory;
the volatile memory storing the default Look Up Table during arc detection calculations;
a Look Up Table identifier for indicating to a user the default Look Up Table; and
a Look Up Table selector mechanism for changing between the plurality of stored Look Up Tables to select a default Look Up Table for use with the detection algorithm.

2. The device of claim 1, wherein the Look Up Tables are pre-allocated into fixed memory regions of the nonvolatile memory.

3. The device of claim 1, wherein the Look Up Tables are designated by common household room locations.

4. The device of claim 1, wherein the identifier is one of a visible lighting sequence or a specific trip delay after a Push To Test routine.

5. The device of claim 1, wherein the device is a CAFI circuit breaker and the Look Up Table selector mechanism utilizes at least one of a Push To Test switch and an On/Off switch of the CAFI circuit breaker.

6. The device of claim 1, wherein the device is a CAFI circuit breaker and the Look Up Table selector mechanism utilizes at least one of a Push To Test switch and an On/Off switch of the CAFI circuit breaker.

7. An arc fault interrupting circuit breaker device having:
a processor for determining the occurrence of an arc event within a branch circuit connected to the circuit breaker;
a nonvolatile memory containing a Bootloader, firmware, and a plurality of Look Up Tables designed for arc events of different load profiles; and
volatile memory for loading a default one of the Look Up Tables and operating the default Look Up Table in conjunction with the processor of the circuit breaker.

8. The device of claim 7 wherein the firmware further includes a detection algorithm using parameter values stored in the Look Up Tables.

9. The device of claim 7, further including a Look Up Table identifier for indicating to a user the default Look Up Table to be used with the detection algorithm.

10. The device of claim 7, further including a Look Up Table selector mechanism for changing between the plurality of stored Look Up Tables to select a default Look Up Table for use with the detection algorithm.

11. The device of claim 7, wherein the Look Up Tables are pre-allocated into fixed memory regions of the nonvolatile memory.

12. The device of claim 7, wherein the Look Up Tables are designated by common household room locations.

13. The device of claim 9, wherein the identifier is one of a visible lighting sequence or a specific trip delay after a Push To Test routine.

14. The device of claim 7, wherein the device is a CAFI circuit breaker and the Look Up Table selector mechanism utilizes at least one of a Push To Test switch and an On/Off switch of the CAFI circuit breaker.
